(19) United States
(12) Patent Application Publication
(10) Pub. No.: US 2014/0373869 A1
(43) Pub. Date: Dec. 25, 2014

(54) METHOD FOR REMOVING SOLDER BALLS FROM CHIP

(71) Applicant: CSMC TECHNOLOGIES FAB 1 CO., LTD., Jiangsu (CN)

(72) Inventors: Jincheng Wang, Jiangsu (CN); Wei Zhang, Jiangsu (CN)

(21) Appl. No.: 14/369,120

(22) PCT Filed: Nov. 8, 2012
(86) PCT No.: PCT/CN2012/084325

§ 371 Date: Jun. 26, 2014

(30) Foreign Application Priority Data
Dec. 29, 2011 (CN) 201110451503.7

(51) Int. Cl. H01L 21/02; H01L 21/66

(52) U.S. Cl. CPC H01L 21/02076; H01L 22/14
USPC 134/1.3

(57) ABSTRACT

A method for removing solder balls (103) from a chip (102) comprises: immersing a chip (102) provided with solder balls (103) in a corrosive solution, the corrosive solution being prepared with a nitric acid solution having a concentration of 70% and deionized water at a volume ratio of 1:1 (301); taking out the chip (102) for rinsing (302); and placing the chip (102) into a container filled with water for ultrasonic oscillation cleaning (303). The corrosive solution prepared with a nitric acid solution having a concentration of 70% and deionized water at a volume ratio of 1:1 can completely remove the solder balls (103) from the surface of the chip (102) without affecting pads (201).

### FIELD OF THE INVENTION

The present invention relates to a field of semiconductor manufacturing technology, and more particularly relates to a method for removing solder balls from a chip.

### BACKGROUND OF THE INVENTION

Integrated circuit (IC) packaging means meeting and guiding circuit pins of a chip to an external connector through a conducting wire, so as to connect other components. Package type refers to a shell used to install a semiconductor integrated circuit chip. It not only installs, fixes, seals, and protects the chip and enhances the electric performance, but also connects the contact of the chip and the pins of the shell with wires, and the pins further connect to the other components through the wires on a PCB, implementing the connection of the chip and the external circuit.

FIG. 1 is a schematic diagram of a conventional IC package structure. According to FIG. 1, the IC package structure includes a base board 101, a chip 102, a plurality of solder balls 103 and filling material 104. The chip 102 is configured above the base board 101, load bearing by the base board 101. The solder balls 103 are configured between the chip 102 and the base board 101, so as to fix the chip 102 on the base board 101. The filling material 104 is configured between the chip 102 and the base board 101, surrounding the solder balls 103, so as to reduce the stress generated by the thermal expansion of the base board 101 and the chip 102.

FIG. 2 is a partial enlarged view of the conventional IC package structure. According to FIG. 2, a solder pad 201 is configured on the chip 102 to electrically connect to external components, and a passivation layer 202 is configured on places without the solder pad 201 on the chip 102. A polymer layer 203 is configured on the passivation layer 202 to provide a buffer during the manufacturing of the solder balls 103 and the assembling of the chip. A solder ball 103 is configured above the solder pad 201 of the chip 102, and an under ball material (UBM) 204 is configured between the solder 103 and the solder pad 201. The UBM 204 not only agglutinates the solder ball 103 to the solder pad 201, but also prevents the tin from spreading to the solder pad 201, and reduces the contact resistance between the solder ball 103 and the solder pad 201.

When the IC package structure becomes invalid and fails to work normally, it is necessary to find out the failure cause. In order to check out the failure point probably exists under the solder balls 103, the solder balls 103 are usually removed during a failure analyzing. In addition, sometimes the condition of the failure analyzing is complex, it is necessary to repackage the chip 102, bonding gold wire or aluminum wire, but the chip 102 can not be repackaged if the solder balls 103 are still on it, so the solder balls 103 should be removed. Usually, aqua regia (mixed solution of nitric acid and hydrochloric acid) is used to corrode and remove the solder balls 103, however, aqua regia reacts with all metal, and the reaction is fast, so it is easy to damage the solder pad 201 under the solder balls 103, causing a electrical parameters change of the chip 102.

Therefore, it is necessary to provide a method for removing the solder balls from the chip to solve the problem of the conventional technology.

### SUMMARY OF THE INVENTION

A concept of a series of simplified form is introduced in part of the contents of the invention, which will be described in further detail in the specific embodiments section. The invention is not meant to be part of the contents of trying to define a key feature and the necessary technical features of the claimed technical solution, but that does not mean trying to determine the scope of protection of the claimed technical solution.

In order to solve the problem of the prior arts, the present invention provides a method for removing the solder balls from a chip, includes: immersing a chip having solder balls in a corrosive solution, the corrosive solution being prepared with a nitric acid solution having a concentration of 70% and deionized water with a volume ratio of 1:1; taking out the chip and rinsing the chip with water; and placing the chip into a container filled with water and cleaning the chip using ultrasonic oscillation.

Preferably, the chip is immersed in the corrosive solution for 10 to 15 minutes.

Preferably, the rinsing time of the rinsing step is greater than or equal to 30 seconds.

Preferably, the oscillating time of the ultrasonic oscillation cleaning is greater than or equal to 40 seconds.

Preferably, the oscillating time is 1 to 2 minutes.

By using the corrosive solution prepared with a nitric acid solution having a concentration of 70% and deionized water at a volume ratio of 1:1, the solder balls can be completely removed from the surface of the chip without affecting pads.

### BRIEF DESCRIPTION OF THE DRAWINGS

The following drawings of the present invention are used to understand the invention as a part of it. The drawings show a embodiment and the description of the embodiment, so as to explain the principle of the invention, in which:

FIG. 1 is a schematic diagram of a conventional IC package structure;

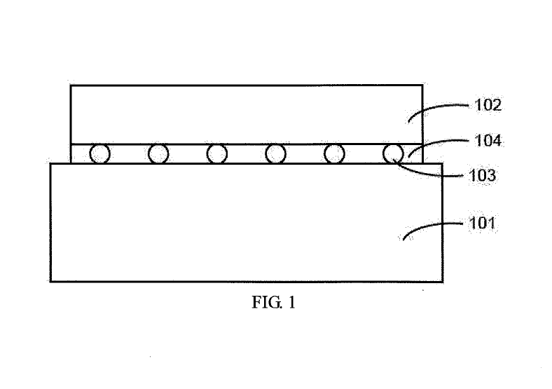

FIG. 2 is a partial enlarged view of the conventional IC package structure; and

FIG. 3 is a process flow diagram of an embodiment of removing solder balls from a chip.

### DETAILED DESCRIPTION OF THE EMBODIMENTS

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. In the drawings, the size and the relative dimension of layers and areas may be exaggerated for clear. Like numbers refer to like elements throughout.

It should be understood that if a component or a layer is described as “on”, “adjacent to”, “connected to” or “coupled to” another component or layer, it may be directly configured on, adjacent to, connected to or coupled to the other component, or there may be a mediate component or a mediate layer. Rather, if a component or a layer is described as “directly on”, “directly adjacent to”, “directly connected to” or “directly coupled to” another component or layer, mediate component or mediate layer does not exist.

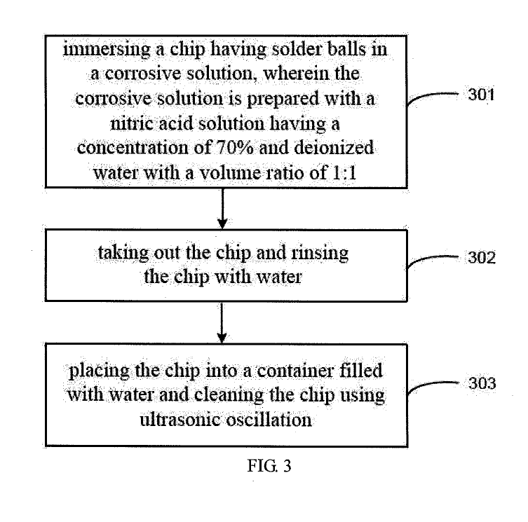

The present invention provides a method for removing solder balls from a chip. FIG. 3 is a process flow diagram of an embodiment of removing solder balls from a chip. The method of the present invention will be described more fully hereinafter with reference to FIG. 3.

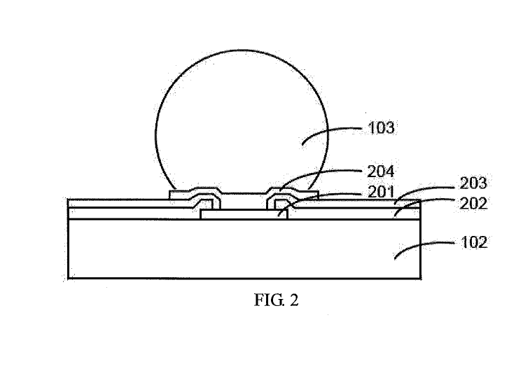

Step 301 is implemented, a chip having solder balls is immersed in a corrosive solution, and the corrosive solution is prepared with a nitric acid solution having a concentration of 70% and deionized water at a volume ratio of 1:1. When the chip having solder balls is placed in the corrosive solution, and the UBM 204 and the polymer layer 203 (referring to FIG. 2) of the chip is easily reacted with the corrosive solution, so that the solder balls will automatically peel off.

Furthermore, in order to make the corrosive solution fully react with the UBM and the polymer under the solder balls, the immersing time should be as long as possible, however, pads (usually made of aluminum) under the solder balls may be damaged if the immersing time is too long, thus, preferably, the chip is immersed in the corrosive solution for 10 to 15 minutes.

Step 302 is implemented, the chip is taken out and rinsed.

The chip is taken out of the corrosive solution and rinsed with water, so as to remove the corrosive solution remaining on the chip. Preferably, the rinsing time of the rinsing step is greater than or equal to 30 seconds.

Step 303 is implemented, the chip is placed into a container filled with water, and cleaned by ultrasonic oscillation.

Ultrasonic oscillation can further clean the corrosive solution remaining on the chip, and remove the solder balls, the UBM and the polymer that have peeled off from the chip. After the ultrasonic oscillation, all the solder balls on the chip are removed, so that the chip can be failure analyzed and repackaged.

Preferably, the oscillating time of the ultrasonic oscillation is greater than or equal to 40 seconds. In order to prevent a too long oscillating time affecting the structure and the electrical properties of the chip, preferably, the oscillating time is 1 to 2 minutes.

By using the corrosive solution prepared with a nitric acid solution having a concentration of 70% and deionized water at a volume ratio of 1:1, the solder balls can be completely removed from the surface of the chip without affecting pads.

Although the present invention has been described with reference to the embodiments thereof and the best modes for carrying out the present invention, it is apparent to those skilled in the art that a variety of modifications and changes may be made without departing from the scope of the present invention, which is intended to be defined by the appended claims.

What is claimed is:

1. A method for removing solder balls from a chip, comprising:
immersing a chip having solder balls in a corrosive solution, wherein the corrosive solution is prepared with a nitric acid solution having a concentration of 70% and deionized water with a volume ratio of 1:1;
taking out the chip and rinsing the chip with water; and
placing the chip into a container filled with water and cleaning the chip using ultrasonic oscillation.

2. The method according to claim 1, wherein the chip is immersed in the corrosive solution for 10 to 15 minutes.

3. The method according to claim 1, wherein the rinsing time of the rinsing step is greater than or equal to 30 seconds.

4. The method according to claim 1, wherein the oscillating time of the ultrasonic oscillation cleaning is greater than or equal to 40 seconds.

5. The method according to claim 4, wherein the oscillating time is 1 to 2 minutes.
